(19) United States
(12) Patent Application Publication
(10) Pub. No.: US 2002/0020903 A1
(43) Pub. Date: Feb. 21, 2002

(54) Chip card with increased card security

(76) Inventors: Hans-Diedrich Kreft, Dassendorf (DE); Michael Jenning, Hamburg-Othmarschen (DE)

Correspondence Address: Kevin W. Guynn, SONNENSCHEIN NATH & ROSENTHAL, Wacker Drive Station, Sears Tower, P.O. Box #061080, Chicago, IL, 60606-1080, US

(21) Appl. No.: 09/780,852

(22) Filed: Feb. 9, 2001

Related U.S. Application Data
(63) Continuation-in-part of application No. PCT/EP99/05841, filed on Aug. 10, 1999.

(30) Foreign Application Priority Data
Aug. 10, 1998 (DE) 198 36 045.2
Aug. 11, 1998 (DE) 198 36 218.8
Aug. 15, 1998 (DE) 198 36 934.4

(51) Int. Cl. H01L 23/02; H01L 23/48

(52) U.S. Cl. 257/679; 257/922; 257/531

(57) ABSTRACT

The present invention relates to microchip cards which are capable of operation both as a contactless card and as a contract card. The card is provided with a coil that prevents any piracy thereof through voltage peaks.

This application is a continuation-in-part application of another international application filed under the Patent Cooperation Treaty on Aug. 10, 1999 and bearing Application No. PCT EP99/05841 and listing the United States as a designated and/or elected country. The entire disclosure of this latter application, including the drawings thereof, is hereby incorporated in this application as if fully set forth herein.

### BACKGROUND OF THE INVENTION

The invention relates to a chip card with increased card security, having at least one semiconductor chip with a memory in which, for the energy supply of the chip and for the bi-directional data transmission via a terminal from and to the chip, various transmission means are provided such as galvanic contacts and/or at least one contactless coil, whereby the energy and data transmission of the chip takes place via one or more first contacts of the terminal to one or more second contacts on the chip card via electrical connection lines between the second contacts and the chip, whereby in the chip, an electronic circuit is provided that autonomously supplies at least one electric signal which indicates whether the chip card is being electrically supplied via contacts or via the coil.

German printed patent document DE 39 35 364 discloses a chip card that has an electronic chip with a memory, contacts and contactless transmission means such as coils and/or condensers which are embedded in the card material and which, for purposes of supplying energy to the chip, exchange energy and bi-directional data with a terminal via the contacts or else contact-free. The chip of the chip card has an electronic circuit (2.1.2) which generates a logical signal that, depending on the occurrence of voltage at the contacts or at a coil, is logically “high” or logically “low”. As a result, the chip card is autonomously capable of deciding whether it is being addressed via the contact-coupled segment or via the contactless segment and consequently, it functions accordingly. This chip card, which is also called Dual Interface Card or CombiCard, is likewise described in the literature reference Helmut Lemme, Der Mikrorechner in der Brieftasche [The microcomputer in your wallet], Elektronik 26/1993, pp. 70-80. This chip card offers considerably greater reliability than the simple contactless cards. German printed patent document DE 44 43 980 also describes connecting the coils and the chip in a special manner.

By measuring the electric power consumption and/or the glitches in the terminal, it is possible to acquire information about the mode of operation of the chip. The power consumption varies, for example, depending on which instructions are being processed in the chip. The power consumption of a contact card can be measured, for instance, in a terminal into which the card is inserted, in that a power consumption measurement is performed at the contacts of the card. It is also possible to acquire information about the mode of operation of a chip in that magnetic fields outside of the chip of a card are measured. Likewise, glitches, as effects of temporally changeable power consumption of the chip or of chip components in the card, can serve as a source of information about the mode of operation of the chip. The execution of various program instructions entailing different levels of power consumption can be a cause of the glitches. Such glitches can also be fed into a microprocessor in order to interfere with the functional flow as a result of which, for example, encryption methods in the cards can be surreptitiously accessed; Helmut Lemme: “Wie sicher sind Chipkarten?” [How secure are chip cards?], ELEKTRONIK No. 16 dated Aug. 4, 1988, starting on page 44.

Printed United Kingdom patent document GB-A 2,321,726 discloses an electrical circuit for regulating in order to keep the energy constant in data carriers that function contact-free and that can be held at various distances from terminals so that the energy transmission to the data carrier is different. For compensation purposes, the data carrier has a receive circuit with a rectifier that has two outputs. A comparator discriminates the difference between the two output voltages and generates a control signal whose amplitude is proportional to this difference. A plurality of reactances that can be switched on or off, for example, condensers, are influenced by the control signal in such a way that, for purposes of energy optimization, a resonance circuit with resistors and coils can be switched on or off.

Moreover, U.S. Pat. No. 5,773,812 describes a chip card with contacts or coils for contact-coupled or contactless energy and data transmission. The chip card has an exchangeable contact block that serves, on the one hand, to protect the chip and, on the other hand, as a sensitive switching element for electronic purposes, so that the electronic components of the chip can be switched on and off for remote transmission.

### SUMMARY OF THE INVENTION

The invention is based on the objective of blocking glitches that form in the chip of a card and that, if metrologically evaluated outside of the card, can provide information about the operating mode of the chip so that an evaluation is reliably prevented; at the same time, surreptitious access to the card by feeding in high-frequency signals is to be ruled out. In addition, data lines and clock lines are to be protected against surreptitious access via glitches. The security of chip cards is to be increased with the means described.

The objective is achieved according to the invention in that, as a function of the signal of the circuit, the two electric connection points of the coil that otherwise serves for contactless energy and data transmission can be serially connected either in one of the connection lines or in the coils in the two connection lines between the chip and the contacts, as a result of which glitches that are transmitted with high frequency components through the lines from the contacts to the chip or vice versa are blocked by the coil or coils.

### BRIEF DESCRIPTION OF THE DRAWINGS

FIG. 1 illustrates a block diagram with a terminal and a chip card having contacts as well as a terminal with a chip card having a coil embodying the principles of the present invention.

FIG. 2 illustrates a specific embodiment of a chip card as shown in FIG. 1.

FIG. 3 illustrates individual coil windings in greater detail.

FIG. 4 is a symbolic representation of the different contact elements of a chip card.

FIG. 5 illustrates the same coil winding in two different orientations, which in one case is connected at one end to the point A1 and at the other end to B1, and in the other case, exactly conversely with the points A1, B1.

FIG. 6 illustrates, in a block diagram form a chip card with preconnected protective devised against surreptitious access.

FIG. 7 illustrates an enlarged representation of the line paths C and B.

### DETAILED DESCRIPTION OF THE PREFERRED EMBODIMENTS

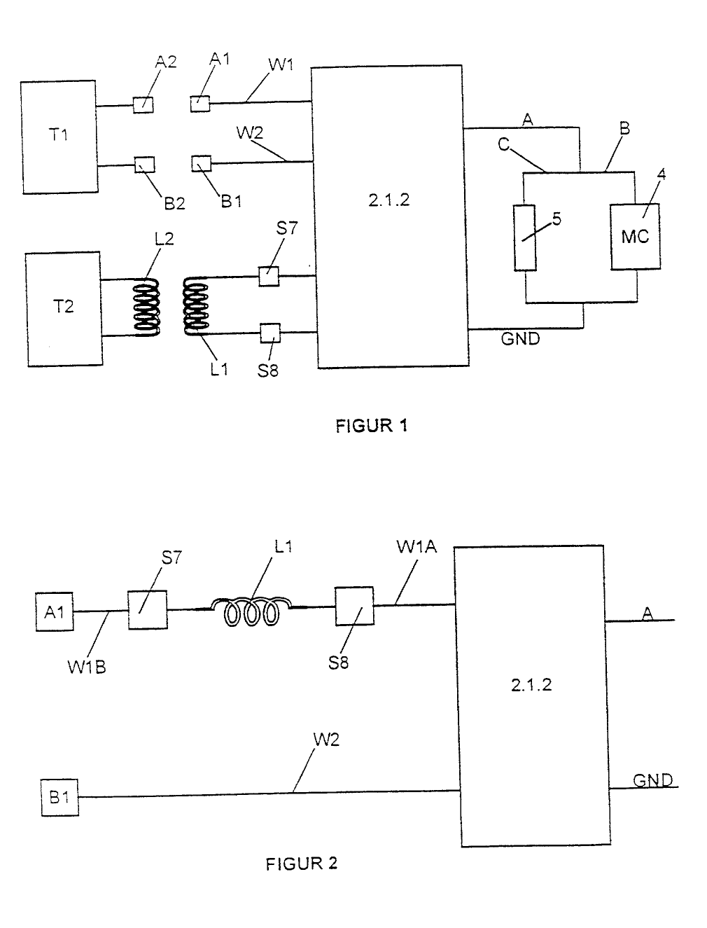

The invention is a chip card with a chip 6 containing various controllable components such as memory and microprocessors. All kinds of means can serve to supply energy to the chip and for the bi-directional data transmission from and to the chip. The card disclosed here has contact connections A1, B1 on the card with the contact connections A2, B2 in the terminal T1, as shown in FIG. 1. In addition, there can also be means for contactless data transmission in the form of coils L1, L2 with terminal L2. Condensers and/or other energy and data transmissions and/or means can also be provided of the type that exists in the form of electronic, miniaturized elements that receive sound or pressure or that capacitively receive electric signals in fingerprint sensors. Via the electric line connection W1, W2, the energy supply of the chip 6 is provided, for example, by contact A1, B1. That is to say, as a rule, the current consumed in the chip flows through the line paths W1, W2. If an electronic component 2.1.2 of the type described in DE 39 35 364 is not present, then W1 is connected directly to line A and A can divide into a least two electric line paths B, C in the chip. Via the contact connection A1 with A2, the chip 6 is supplied with energy from a terminal, for example, by the positive pole of a direct voltage source, whereby B1 with B2 form the associated negative pole, that is to say, the reference potential GND. If at least one coil with inductance L1 is provided on the card and/or in the chip 6, this inductance can be used to block glitches that occur when the power consumption in the chip is switched on or off. The term blocking should be understood to mean that the electrical resistance of an inductance for high-frequency signals is extremely high and these signals cannot overcome the inductive resistance. For this purpose, a coil with inductance L1, with its two electrical connection points S7, S8, is serially connected into the connection line W1, that is to say, into the galvanic connection path between the contact on the card and the chip in the card. Glitches, which are transmitted very readily with their high-frequency components via the lines W1 and/or W2 without inductance, now encounter a high inductance L1 in the transmission path W1, and they are blocked in the manner described above. The inductance also has the same effect for high-frequency signals that are fed in from outside of the card, for example, from a terminal T1 via A2. In this case as well, high-frequency signals in the fed-in glitches (spikes) cannot overcome the inductance L1.

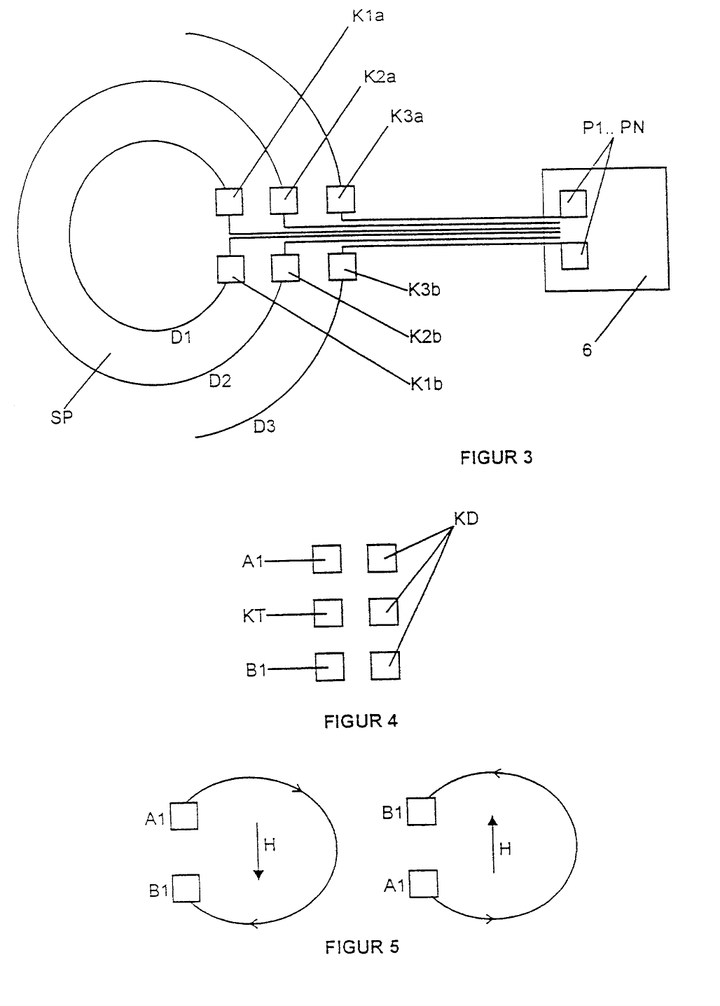

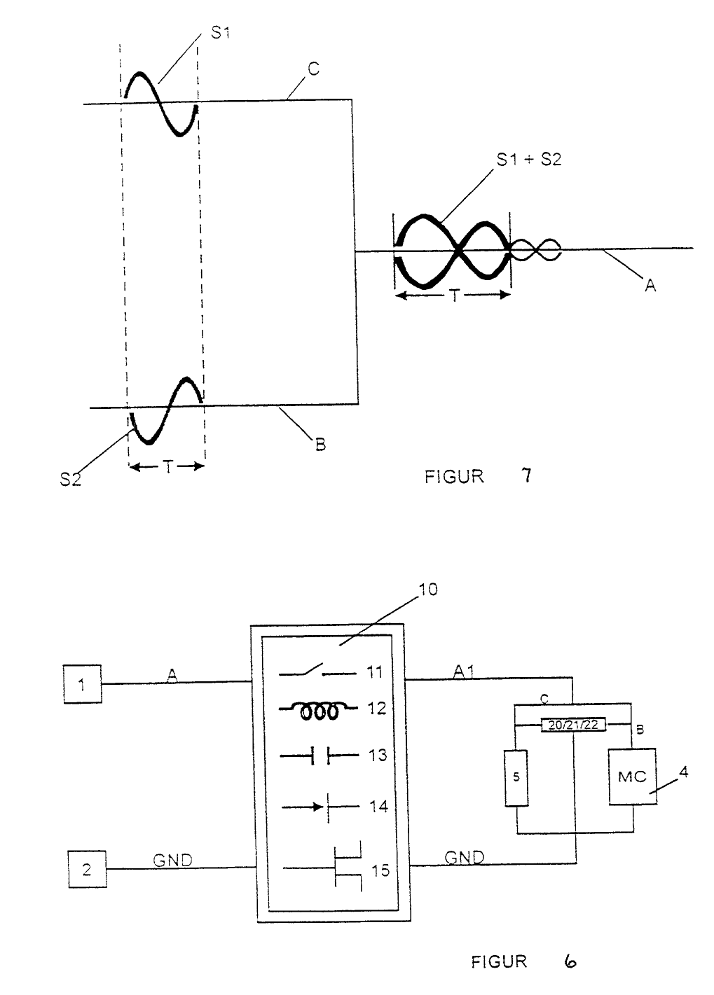

The chip 6 can have means, for example, in the form of electronic switches, with which individual coil windings D1, D2, D3, FIG. 3, of the coil SP can be galvanically connected or disconnected. For this purpose, the individual coil windings are galvanically disconnected in the points K1a/K1b, K2a/K2b, K3a/K3b, and are conducted to different input points P1 . . . PN of the chip 6. The chip can connect the points according to a program or according to a predefined logical allocation. In the described manner, the individual coil windings can be disconnected or interconnected, but the coil windings can also be connected to specific chip components. In this manner, the chip 6 can selectively switch individual coil windings on or off. The directionality of the coil windings with respect to each other can also be changed, as a result of which a fed-in current flows in the windings in the opposite direction. The relationships are shown symbolically in FIG. 5 insofar as, through switching of the chip, the coil points A1, B1 are connected in a reversed manner to a constant source having an unchanged polarity. Here, this results in superimpositions of magnetic fields that cancel each other out outside of the coil windings.

It is possible to connect one or more coil windings of the coil SP with the data inputs and/or with the data outputs and/or with a clock pulse input. In this case, the signals are not fed directly into the chip but rather are conducted via the coil or via individual windings. This entails the advantage that glitches on the data lines or on the clock lines are likewise blocked.

If coil windings are situated close to each other and if they are located in an electromagnetic alternating field, then alternating voltages are generated in the coils by means of inductance. The voltages have opposite directionality (out of phase) as long as the rotational direction of the coils is opposite, that is to say, a current flows in the opposite direction in the case of a virtually parallel winding component. This knowledge can be utilized in that at least a first and a second coil winding of the coil SP are serially connected in the connection line W1 or W2, whereby the directionality of the first coil winding is opposite to that of the second coil winding in order to compensate for coupled-in inductance voltages by means of an electromagnetic alternating field. When the two coil windings are galvanically connected, the coupled-in voltages cancel each other out with a phase difference as a result of their superimposition.

Measures to filter oscillations can be taken in order to allow certain data frequencies (clock times) to pass as unhindered as possible (with low resistance). The coil SP or the individual windings of this coil can be used for this purpose in a filter circuit, for example, in order to allow only certain frequencies of a voltage to pass. In this manner, the input resistance for clock frequencies can be kept low.

The coil SP or the individual windings can be used in an oscillating circuit. In this manner, the chip could, for instance, generate its own frequency, as a result of which its own clock pulse would be available and it differs from the clock frequency that is available from the terminal.

Individual windings of the coil SP can be used for galvanic uncoupling of the transmission of data and/or clock pulses. For this purpose, the individual coil windings must be connected in such a way that they are opposite from each other as is the case with a transformer for data and/or energy transmission. Due to their geometrical proximity, the coil windings are coupled electromagnetically and thus form the desired transformer for the purposes of reaction-free transmission of energy and/or data. According to this description, it is possible to provide energy and/or data to the chip of a card from a terminal by means of galvanic contact, whereby a complete galvanic uncoupling is achieved via the coil windings. Glitches cannot be transmitted into the chip via the data lines or via the clock line.

A complete galvanic uncoupling of all of the electric connections occurs when the direct voltage applied to the contacts A1/A2 is converted in the chip into an alternating voltage that is subsequently available to the chip via the coil SP or via individual windings of the coil SP and is transformed into a direct voltage in the chip. For this purpose, known elements such as switching regulators and rectifiers, are needed on the chip. The described transformer circuit can be used for data uncoupling.

In order to generate an alternating voltage from a direct voltage, the chip 6 can reverse the coil points A1, B1 of a first coil winding (winding group) by means of switching so that, in one case, the current from a direct voltage source flows through the winding(s) from A1 to B1 and, in the other case, from B1 to A1. See FIG. 5. In adjacent coil windings, alternating voltages are generated in this manner by electromagnetic coupling and they can be rectified in the chip 6 with known means.

For the production of chip cards, it can be advantageous to install the coil SP with its windings below the contact surfaces. Since contact surfaces are present in the invention disclosed here and the chip is normally mounted below the contact surfaces, the coils can also be installed below the chip surface. In this manner, the contacts, the coil and the chip form a mechanical unit as a module. The module provides all electronic functions that a chip card should be able to fulfill when it is used as intended. Thus, the entire functioning of the module has to be tested before it is delivered and there is no need for connections between the chip and the coil that would have to be made by the card manufacturer.

There are cards in use that have means in the chip and/or on the card that can acquire energy and data either via contacts and/or contact-free. In addition to the contacts for supplying energy and/or data, the means for contactless transmission can additionally be used to galvanically disconnect the chip from the contacts. Since coil windings, rectifiers and condensers are available in the cards that function contact-free, these can also be used for creating a supply via contacts.

If at least two first coil windings are used for the galvanic energy supply and if current flows through them electrically in opposite directions, then the effect of blocking glitches is retained. If these coil windings are interconnected in the chip at one point, then coupled-in voltages can also be compensated for. Via a number of second coil windings, additional contact inputs for data and clock pulses can couple in data and clock pulses to a number of third coil windings by means of a transformer. Coil windings that are located close to each other on the card function as transformers. If digital data and signals were coupled electromagnetically by coil windings, then the coupled data is present in analog form on the chip. In the chip, digital data and clock pulses can be can be acquired from this data by using suitable and known means. Since there is no longer a galvanic connection between the data and the clock pulse originally fed in via a contact and those newly generated in the chip, all possible analog signals (glitches) that were present at the contacts are uncoupled and additionally present in an undisturbed digital form in the chip as a result of the new generation. Due to the opposite directionality of the at least two first windings, the galvanic energy supply is free of coupled-in data or clock signals that could occur due to the spatial proximity of the coils on the card. The circuitry described here completely prevents the feeding-in or reading-out of glitches from or to the card. Surreptitious access to chip functions is made more difficult and the card security is increased.

The coil winding surfaces, i.e. the largest surfaces that the coil winding comprises, can be positioned in such a way that they are not arranged parallel to the largest card surface. These can be, for example, small rod magnets that are embedded in the material of a card.

One or more coils can be arranged twisted together with each other, so as to increase their magnetic coupling in this manner. An arrangement adjacent to each other can be advantageous if a shared carrier with magnetic properties is to be used. The carrier can also be made of a mechanically flexible material in order to withstand bending of the card.

A terminal T1 ascertains the input conditions on a regular contact card in a certain combination of electrical parameters. If the terminals currently on the market are to continue to carry out their function unchanged, and if cards with the means described here are to be used, then the chips in the card have to provide the electrical parameters in such a way that no change or only an insignificant change can be detected in the terminal. For this purpose, means such as resistors or else condensers and switches can be used which are combined with the coils in a suitable manner. When data is transmitted, a high load resistance on the coils will suffice since no power is to be transmitted. In the case of power transmission by a clock pulse or coil, a regulated resistance can be applied.

The coil SP, which is present with individual intermediate taps, can be connected to a chip in a suitable manner. The intermediate taps can be present as contacting surfaces on a flat carrier material such as film or paper. These contacting surfaces of the intermediate taps correspond to the positions of contacting surfaces of a module consisting of a chip and of contact elements. The chip connections of a chip can lie below the contacts. An electrical connection can be made when the coil contact and the chip are brought together. Suitable materials for electrical and/or mechanical connection of the module and the carrier element can be present on the contacting surfaces.

The coil that is embedded in the card material can be used with its inductance L1 to ensure the blocking of glitches. An advantage associated with this coil is its high inductance, which is necessary in order to ensure a high energy transmission from coil L2 in the terminal T2 to the card coil L1. A high inductance increases the blocking effect against the transmission of glitches.

The electronic circuit 2.1.2 of the chip 6 generates a logical signal that, depending on the occurrence of voltage at the contacts or at a coil, is logically “high” or logically “low”. The logical value of the signal can be used, for example, in order to control switches in such a way that the points S7, S8 of a coil are serially brought into the line path W1. For this purpose, the path W1 has to be opened and the coil S1 has to be brought into the opened segment. In this manner, the coil is connected into the electrical connection path from the chip in the card to the supply contact A1 on the card. Therefore, a card with a coil that can function in the contactless mode as well as in a contact-coupled mode can be protected in a special manner against surreptitious access to glitches on the card. Therefore, the coil of the card has two functions. In the first one, it serves as a transformer coil for energy and data, whereas in the second one, it serves as an inductive resistor to block high-frequency components in glitches. As a result, the cards on the market under names such as CombiCard or “Dual Interface Card” can protect the contact function of a card in a special manner and, at the same time, offer the advantages of contactless operation.

When means are used that avoid or compensate for the effects of temporally changeable power loads and/or the occurrence of glitches, in addition to their use, the advantage arises that a division of the current path A into the paths B, C leads to a constant current in A, in that the means 5 switches the power consumption on or off. This gives rise to a special advantage. Since a constant current flows in A, it also flows through the coil having the inductance L1. As is well known, self-inductance occurs in a coil when the current flow fluctuates, whereby the self-inductance increases as L1 rises. Self-inductance can cause undesired effects, for example, additional glitches, in a circuit. When the current flow is constant, no self-inductance occurs. If the coil with L1 lies in the line path A or in a prolongation thereof, the coil is protected against self-inductance by the constant current flow in A. The constant current flow in A can be superimposed by spikes/glitches that are caused by switch slopes during the switching of loads of the means 5 and/or of the means 4.

In FIG. 1, T1 designates a terminal for chip cards having contacts A2, B2 while T2 designates a terminal with a coil and inductance L2. The contact A1 provides the supply voltage via the electrical line W1, while the contact B1 provides the reference potential GND for a card 6 via the electrical line W2. A coil L1 on the card or on the chip is shown with its inductance L1. This coil L1 is provided with the connections S7, S8, which are switchable, that is to say, they can be switched on and off. The component 2.1.2 symbolically represents a circuit of the kind disclosed in DE 39 35 364 which serves to indicate the operating mode via the contacts A1, B1 or via the coil L1 here. The microprocessor 4, MC, receives its direct current—independently of its origin or generation—via the line path A, whereby A can be divided into the paths B, C. The reference numeral 5 designates a circuit means that can switch on power or current in path C in a form that leads to a constant current flow in line A.

In FIG. 2, a special embodiment of the block diagram of FIG. 1 is shown. Using the information from the means 2.1.2, the coil with the inductance L1 is connected in series in the line path W1, as a result of which W1 divides into the component W1A between the chip or component 2.1.2 and the coil, and into the component W1B between the coil and the output contact A1 of the chip card to the terminal contact A1. The line path W2 is continuous.

FIG. 3 shows individual coil windings D1, D2, D3 that lie with their opposite ends on the points K1a, K2a, K3a, and K1b, K2b, K3b, whereby these points are connected to the points P1 . . . PN of the chip.

FIG. 4 symbolically shows the different contact elements of a chip card. KD designates the contacts for data transmission, and KT designates the contact for clock pulse transmission. A1, B1 are the known contacts for the supply of direct current.

FIG. 5 shows the same coil winding twice which, in one case, is connected at one end to the point A1 and at the other end to B1 and, in the other case, is connected exactly conversely with the points A1, B1. Depending on the connection of the points, the magnetic field H generated by a current has the opposite directionality.

In FIG. 6, the contact surfaces 1, 2 establish contact between the chip card and a terminal. Via the line connection A, the total power supply to the chip 6 is provided from the contact side. There is a means 10 in the line connection A, which contains, for example, switch(es) 11, coil(s) 12, condenser(s) 13, diode(s) 14, and electronically controllable switching elements 15 such as transistors, MOSFET, etc.

The output of the means 10 is a line connection A1 that divides into line paths B, C. The line path B contains the chip component 4 with the microprocessor MC and, if applicable, the functional component 3 as a consumer of electric power; the line path C contains the functional component 5 as a consumer corresponding to the consumption in the line path B. Between the line paths C and B are the means 20, 21, 22 according to the description above, and they correspond to the connection “S” of FIG. 1.

FIG. 7 shows the line paths C and B with two glitches S1 and S2 drawn in. Since the current and effect directions in the line paths C and B are connected in opposite directions, the phases of the glitches S1 and S2 are also in opposite directions. If the glitches S1 and S2 are conducted to a shared point of Line A, they become superimposed and complement each other to zero when they occur simultaneously in the line connection A. The duration of a first full oscillation is indicated by T.

The explanations below serve for the further explanation of the invention as do FIGS. 6 and 7. In the line path C, there are electronic means 5 that make it possible to compensate for the current consumption or power consumption in the line path B. The means 5 can be electronic elements such as a resistor, a condenser, a coil, a power source or a combination of these elements. As a rule, the means 5 will be an ohmic resistor.

Associated with the switching on or off of electric power consumers in the current path C and/or B are oscillation processes of electric quantities whose frequencies are high or low when the switching times are short or long. The oscillation processes occur, for example, as glitches that are transmitted via electric lines A, B, C and whose evaluation in the card or outside of the card gives information on the switching on or off of loads and/or consumers. Means 9 can be provided on the chip 6 that avoid or compensate for the occurrence of switching peaks and/or glitches during the switching on or off of power consumers in the path C. In the simplest case, condensers are provided that, for instance, connect glitches with the reference potential, thus low-ohmically discharging the condenser as well as the alternating voltage resistor. The condensers can connect the lines B, C with the ground (the reference potential, e.g. point 2).

Program calls in a processor are determined by a time sequence. For a certain program call at point in time t2, the power consumption of means 5 can be predictably changed in that the change takes place at point in time t1, whereby t1 lies between a small time interval of the size 2×d^{t} between t2−d^{t} and t2+d^{t}. Through this synchronized “simultaneous” switching of the means 5 at the point in time t2, at virtually the same point in time, glitches can be generated whose phases are shifted according to FIG. 7 by 180 degrees, which is why they eliminate each other as long as they are transmitted simultaneously via lines B, C to line A. FIG. 7 illustrates that, in branch B, the phases of the occurring glitches are exactly opposite to those in branch C. This results from the reverse power switching of means 5 to the consumer 4.

If the lines B and/or C are provided with means 20 for purposes of filtering electromagnetic oscillations, glitches can be discharged at a certain basic frequency to the reference potential of the chip 6. For example, a filter for the frequency Fd is permeable, e.g. filters from the elements that consist of condensers, coils; a pulse with a basic oscillation Fd can pass the filter and can be discharged against the reference potential of the chip.

Between the lines B and C, electronic means 21 can be provided that constitute an electronic oscillating circuit 22 with a certain resonance frequency fr. Such an oscillating circuit requires an energetic excitation in order to oscillate. The energetic excitation consumes energy. Energy is present in the glitches that are to be found on the lines B and/or C. These glitches contain a basic frequency fs. When fr matches fs, then the oscillating circuit is excited so as to oscillate, the excitation energy is taken from the glitches, as a result of which the energy of the glitches is decreased.

Between the inputs 1, 2 as power transmitters and the means, 4, 5 as power consumers, there is a means 9 for the generation of an alternating voltage. This alternating voltage is converted in the means 9 into a direct voltage that serves as the source of power for the chip 6. In the case of a contact-coupled chip card, a source of direct current is preferably available as the input power, whereas in the case of a contactless chip card, a source of alternating current (rectification of the alternating voltage transmitted by a transformer) is preferably available. In both cases, the means 9 generates a direct voltage and a direct current at its output, which supply the chip 6. The reason for this conversion is the uncoupling of the inputs 1, 2 from the circuit components on the chip 6, as a result of which surreptitious access via glitches is to be avoided, which can be confirmed during the power connection via the current path A. In this case, the means 9 serves as a power supply to the chip 6 and the external power supply via 1 only serves as an indirect power supply to chip 6. In order to turn a constant power source at 1 into an alternating source, the means 9 can interrupt or open the power feed via the electric line A. Thus, an oscillation process is present in the electronic components in the means 9. If, for example, a memory for electric charges (capacity) is present in 9, then a source of direct voltage source can be generated from the oscillation in the means 9. This power can be made available via A1 to the chip 6 to that it can maintain its function. Many forms are conceivable for the configuration of the means 9. From the power that is fed in via A, a periodical (continuous, periodical; sinusoidal wave; discontinuous, periodical digital rectangular pulses) power feed into the means 9 is generated. From this periodical feed, a constant power feed is generated in the electrical path A1. In this manner, glitches are not transmitted directly into the line path A since they are electrically uncoupled.

If it is to be avoided that information on the operating mode of the component 4 is obtained by the measurement of electrical data at point 1, the electronic elements of a contactless energy and/or data feed can advantageously also be used for the contact supply. If the contactless feed is effectuated, for example, by a transformer circuit via coils, diodes, condensers (elements in component 10), these elements can also be used with a direct voltage feed in that the direct voltage is periodically interrupted (converted into an oscillation) and this is subsequently rectified with the means or with some of the means in the means 9. For this purpose, the means 9 can utilize electronic elements 10 as well as mechanical switches 11 and/or electronic switches 15 and/or coils 12 and/or condensers 13 and/or diodes and/or elements for generating logical signals. Such elements are described in DE 39 35 364, which also describes how a logical signal is generated with which a distinction can be made from which input (contact-coupled input or contactless input) the supply is coming. Thus, a microprocessor 4 would not be directly connected to the connection 1 but rather only indirectly via the components in 9 as they are used for acquiring power from a contactless transmission of energy and/or data. In the means 9, at least some of the elements 10 are used in order to use a first constant voltage source at A to generate a second constant voltage source at A1. This circuit has the advantage that, with a CombiCard (Dual Interface Card) known on the market among those skilled in the art, the components that are needed for the rectification of an alternating voltage are also used for feeding in a direct voltage. Since by means of component 9, together with the use of the elements 10, evidence of the function of the microprocessor 4 can be eliminated, a chip has to be made that functions in the contact-coupled mode as well as in the contactless mode, and that avoids the possibility of surreptitious access in the manner described.

The invention is especially useable in chip cards in order to increase the card security. The benefit of the invention especially lies in that, through the use according to the invention of inductances in the chip card, surreptitious access to the card by means of glitches can be effectively prevented. Surreptitious access to the card by feeding in high-frequency signals is ruled out. In addition, data and clock lines are protected against surreptitious access by means of glitches. Thus, with the means according to the invention, the security of the card is increased.

As is apparent from the foregoing specification, the invention is susceptible of being embodied with various alterations and modifications which may differ particularly from those that have been described in the preceding specification and description. It should be understood that we wish to embody within the scope of the patent warranted hereon all such modifications as reasonably and properly come within the scope of our contribution to the art.

I claim as my invention:

1. A chip card with increased card security, having at least one semiconductor chip with a memory in which, for the energy supply of the chip and for the bi-directional data transmission via a terminal from and to the chip, at least one contactless coil, whereby the energy and data transmission of the chip takes place via one or more first contacts of the terminal to one or more second contacts on the chip card in the form of at least one of galvanic contacts and said at least one contactless coil via electrical connection lines between the second contacts and the chip, whereby in the chip, an electronic circuit is provided that autonomously supplies at least one electric signal which indicates whether the chip card is being electrically supplied via galvanic contacts or via contactless coils, wherein, as a function of the signal of the circuit, two electric connection points of the coil that otherwise serve for contactless energy and data transmission are serially connected either in one of the connection lines or in the coils in the two connection lines between the chip and the second contacts, as a result of which glitches that are transmitted with high frequency components through the lines from the contacts to the chip or vice versa are blocked by the at least one coil.

2. The chip card according to claim 1, wherein the chip comprises means to galvanically disconnect individual coil windings from remaining coil windings of the coil, whereby the chip is arranged to selectively switch individual coil windings on or off.

3. The chip card according to claim 1, wherein one or more coil windings of the coil are connected to third contacts of data inputs and/or data outputs and/or with a clock pulse input.

4. The chip card according to claim 3, wherein at least a first and a second coil winding of the coil are serially connected in one of the two connection lines, whereby a directionality of the first coil winding is opposite to that of the second coil winding, and thus, by means of an electromagnetic alternating field, inductance voltages coupled-in via the coil windings cancel each other out as a result of their phase difference in the case of a galvanic connection of the two coil windings.

5. The chip card according to claim 1, wherein the coil or the individual windings thereof are used in a filter circuit or in an oscillating circuit.

6. The chip card according to claim 1, wherein individual coil windings are used for galvanically uncoupling a transmission of data and/or clock pulses, whereby the coil windings are coupled electromagnetically and form a transformer for purposes of reaction-free transmission of energy and/or data.

7. The chip card according to claim 1, wherein the coil with its windings is installed below contact surfaces of the second contacts, whereby the second contacts, the coil and the chip form a mechanical unit as a module.

8. The chip card according to claim 1 wherein at least two first coil windings of the coil are used for a galvanic energy supply, and current flows through the two first coil windings electrically in opposite directions, whereby said coil windings are interconnected in the chip at one point, as a result of which electromagnetically coupled-in voltages cancel each other out and galvanically fed-in glitches are blocked, whereby additional contact inputs for data and clock pulses couple in data and clock pulses via second coil windings by means of a transformer to third coil windings, and the data and the clock pulses are conducted as analog signals via the third coil windings to inputs of the chip, which generates digital data and clock pulses from the analog data and clock pulses, as a result of which the generated digital data and clock pulses are free of glitches, whereby, due to the opposite directionality of the at least two first windings, the galvanic energy supply is free of coupled-in data or clock signals of adjacent coil windings.

9. The chip card according to claim 1, wherein when the contacts of the chip are used for the transmission of energy and/or data, the coils for the contactless transmission of energy and/or data are additionally used to galvanically disconnect the chip from the second contacts.

10. The chip card according to claim 1, wherein one or more coils are twisted together with each other or arranged parallel adjacent to each other or arranged in such a way that they use a shared carrier with magnetic properties.

11. The chip card according to claim 1, wherein the chip connects the connections to individual coil windings with electronic means that are suitable to simulate electronic conditions comparable to the electronics in a terminal of the type that are present if the individual coil windings are not connected to the connection lines.

12. The chip card according to claim 1, wherein the chip comprises means to galvanically disconnect individual coil windings from the remaining coil windings of the coil, so that the chip can change the directionality of the coils with respect to each other.
